(19) United States
(12) Patent Application Publication
(10) Pub. No.: US 2010/0244068 A1
(43) Pub. Date: Sep. 30, 2010

(54) Method For Applying A Thin-Film Encapsulation Layer Assembly To An Organic Device, And An Organic Device Provided With A Thin-Film Encapsulation Layer Assembly Preferably Applied With Such A Method

(75) Inventors: Bas Jan Emile van Rens, Heemstede (NL); Yvo Hendrik Croonen, Bocholt-Kaulille (BE); Ruediger Lange, Waalre (NL)

Correspondence Address: LEYDIG VOIT & MAYER, LTD, TWO PRUDENTIAL PLAZA, SUITE 4900, 180 NORTH STETSON AVENUE, CHICAGO, IL, 60601-6731, US

(73) Assignee: OTB Solar B.V., Eindhoven (NL)

(21) Appl. No.: 12/599,847

(22) PCT Filed: May 16, 2008
(86) PCT No.: PCT/NL2008/050289

§ 371 Date: Nov. 12, 2009

(30) Foreign Application Priority Data
May 16, 2007 (NL) 1033860

(51) Int. Cl. H01L 51/52; H01L 51/56

(52) U.S. Cl. 257/98; 438/26; 257/E51.022; 257/E51.018

(57) ABSTRACT

A method for applying a thin-film encapsulation layer assembly to an organic device, which comprises a substrate which is provided with an active stack and is then provided with the thin-film encapsulation layer assembly for screening the active stack substantially from oxygen and moisture, wherein the thin-film encapsulation layer assembly is formed by applying at least one organic and at least one inorganic layer applied with PECVD or reactive sputtering, onto the active stack, wherein after application of a first organic layer a metal layer is applied to the first organic layer before an inorganic layer is applied thereto utilizing PECVD or reactive sputtering, wherein the metal layer is applied utilizing a deposition technique that causes relatively little radiation, wherein the metal layer protects the organic layer against radiation upon a subsequent PECVD or reactive sputtering process step for applying an inorganic layer. The invention also relates to an organic device manufactured with such a method.

The invention relates to a method for applying a thin-film encapsulation layer assembly to an organic device, such as for instance an OLED, wherein the organic device comprises a substrate which is provided with an active stack and is then provided with the thin-film encapsulation layer assembly for screening the active stack substantially from oxygen and moisture, wherein the thin-film encapsulation layer assembly is formed by applying at least one organic layer and at least one inorganic layer to the active stack, wherein the at least one inorganic layer is applied with plasma enhanced chemical vapor deposition (PECVD) or reactive sputtering.

Such a method is known from practice. In the known method for applying a thin-film encapsulation layer assembly, a first sealing inorganic layer can be applied to the active stack for protecting the functional layers of the device. Next, a first organic layer is applied onto the inorganic layer on the active stack. After that, a second inorganic layer is applied to the organic layer, forming a further sealing. Also, it is possible to apply further organic and inorganic layers onto these. The inorganic layers are applied using a plasma enhanced chemical vapor deposition (PECVD) or through reactive sputtering. It is further known, when building up the thin-film encapsulation layer assembly, to apply an organic layer as a first layer and then alternately inorganic and organic layers.

It is found that organic devices that are provided with a thus manufactured thin-film encapsulation layer assembly still degrade. After extensive research it is presently supposed that when the inorganic layer, for instance an SiN layer, is applied by means of a plasma deposition technique, such as for instance Electron Cyclotron Resonance (ECR), Inductively Coupled Plasma (ICP) or Expanding Thermal Plasma (ETP), degradation of the organic device occurs because the plasma radiation affects the previously applied organic layer or layers of the thin-film encapsulation layer assembly. Also in reactive sputtering, with an acceptable process time, such plasma loading on the organic layer or layers may be intensive. As a result of the organic layer or layers being affected, materials are released which may harm the active stack, such as for instance the light emitting material layer (for instance the PDOT layer), or the barium of the cathode.

When, however, the inorganic layer is applied utilizing a different deposition technique where the organic (polymer) layer is not affected by plasma radiation, as, for instance, by means of chemical vapor deposition (CVD) not being PECVD or other similar techniques, the deposition rates thereof are relatively low. These may be lower than in plasma deposition by as much as a factor of ten. From the viewpoint of process speed and process efficiency, this is disadvantageous.

Accordingly, the object of the present invention is to provide a method for applying a thin-film encapsulation layer assembly to an organic device without the above-mentioned disadvantages. More particularly, the object of the invention is to provide a method for applying a thin-film encapsulation layer assembly to an organic device, whereby the organic layers of the thin-film encapsulation layer assembly are not affected by radiation of the deposition technique used for applying the thin-film encapsulation layer assembly and whereby at the same time the process speed is relatively high.

To that end, the invention provides a method for applying a thin-film encapsulation layer assembly to an organic device, such as for instance an OLED, wherein the organic device comprises a substrate which is provided with an active stack and is then provided with the thin-film encapsulation layer assembly for screening the active stack substantially from oxygen and moisture, wherein the thin-film encapsulation layer assembly is formed by applying at least one organic layer and at least one inorganic layer to the active stack, wherein the at least one inorganic layer is applied with plasma enhanced chemical vapor deposition (PECVD) or reactive sputtering, characterized in that after application of a first organic layer of the thin-film encapsulation layer assembly a metal layer is applied to the first organic layer before an inorganic layer is applied thereto using PECVD or reactive sputtering, wherein the metal layer is applied to the organic layer using a deposition technique which causes relatively little radiation, wherein the metal layer is arranged to protect the organic layer from radiation upon a subsequent PECVD or reactive sputtering process step for applying an inorganic layer.

Such a metal layer protects the organic (polymer) layer from the influence of the plasma during the plasma deposition of an inorganic layer on the organic layer. So, for instance, visible light, UV radiation, reactive ions, electrons and/or heat and the like will not affect the quality of the organic layer. As a result, degradation of the functional layers of the organic device is prevented, at least limited to a large extent.

Further, the use of the metal layer in the thin-film encapsulation layer assembly affords the advantage that this layer constitutes an extra internal barrier to any moisture and/or oxygen before this can reach the functional layers of the active stack. This enhances the quality of the organic device manufactured with the method according to the invention. Preferably, the plasma enhanced chemical vapor deposition (PECVD) is a technique such as for instance electron cyclotron resonance (ECR), inductively coupled plasma (ICP) or expanding thermal plasma (ETP).

According to a further elaboration of the invention, the metal layer is of a same composition as a cathode present in the active stack. The metals for the metal layers, since these are also used for providing the cathode in the active stack, are already on hand in the manufacturing process of the organic device, which is advantageous from the viewpoint of cost. For instance for a small molecule OLED, both the cathode and the metal layer can then comprise, for instance, lithium and aluminum.

According to a further elaboration of the invention, the metal layer comprises barium and aluminum. The barium not only provides a good adhesion to the organic layer but also has a getter function for capturing moisture and oxygen. A combination of barium and aluminum provides a good protection from the radiation of the plasma. Also, barium and aluminum may already be used in a same manufacturing process for providing the cathode, for instance in a polymer OLED, so that these metals, as mentioned above, are then already on hand for manufacturing the metal layer, which is advantageous from the viewpoint of cost. Also, barium promotes the adhesion of the barium-aluminum layer to the organic layer. Preferably, the metal layer comprises a layer of barium having a layer thickness of preferably between 2 and 10 nm and a layer of aluminum having a layer thickness of preferably between 10 and 800 nm.

In a further embodiment of the invention, it is also possible that the metal layer comprises simple metal, such as for instance chromium, or comprises a combination of an alkali metal, such as lithium, and a metal, such as for instance aluminum. Other metals besides chromium can for instance include aluminum, copper, nickel, zinc, or tantalum. It is also possible that alloys are used.

Preferably, the at least one inorganic layer is a ceramic or a dielectric layer, such as for instance an SiNₓ layer, an SiOₓ layer and the like.

According to a further elaboration of the invention, the deposition technique which causes relatively little radiation, and which is used for depositing the metal, comprises chemical vapor deposition (CVD) not being PECVD, evaporation, sputtering and like deposition techniques.

The use of such a deposition technique for applying the metal layer prevents the organic layer on which the metal layer is applied from being affected.

In an embodiment of the invention, when on the organic device a thin-film encapsulation layer assembly is produced which comprises a number of alternately applied organic and inorganic layers, a metal layer may be deposited on a number of organic layers applied to the organic device.

The thin-film encapsulation layer assembly then comprises a number of filters against the undesired radiation, which improves the quality of protection.

According to a further elaboration of the invention, a first applied inorganic layer of the thin-film encapsulation layer assembly may be applied before the first organic layer thereof is applied. This variant provides the advantage that the active stack cannot be affected by substances released from the organic layer.

According to an alternative further elaboration of the invention, a first applied inorganic layer of the thin-film encapsulation layer assembly may be applied after the metal layer has been applied to the first organic layer of the thin-film encapsulation layer assembly. This variant provides the advantage that the inorganic layer is applied to a metal layer which mostly has a top surface contour that is better suited for adhesion of the inorganic layer than the uncovered active stack of the organic device.

The invention further provides an organic device, such as for instance an organic light emitting device (OLED), preferably manufactured with the method according to the invention, wherein the organic device comprises an active stack which is screened off by a thin-film encapsulation layer assembly of which the inorganic layers have been applied with plasma enhanced chemical vapor deposition (PECVD) or reactive sputtering, wherein the thin-film encapsulation layer assembly comprises a first applied organic layer, wherein to the first applied organic layer at least one metal layer has been applied before an inorganic layer has been applied thereto using PECVD or reactive sputtering, wherein the metal layer has been applied to the organic layer using a deposition technique which causes relatively little radiation, wherein the metal layer is arranged to protect underlying organic layer from radiation upon subsequent application of an inorganic layer using PECVD or reactive sputtering.

With such an organic device, advantages and effects can be obtained equal to those mentioned and described above in respect of the method for applying a thin-film encapsulation layer assembly.

Further elaborations of the invention are described in the subclaims and will hereinafter be further clarified with reference to the drawings, in which:

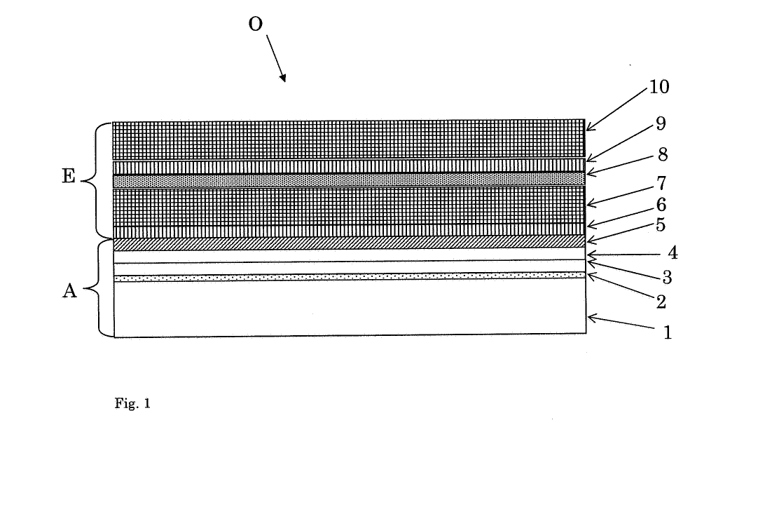

FIG. 1 shows a schematic cross section of a portion of an organic light emitting diode (OLED) according to an embodiment of the invention manufactured utilizing the method according to the invention.

In FIG. 1 a portion of an organic device O is shown. More particularly, the FIGURE shows a portion of an OLED manufactured with the method according to the invention. The OLED O comprises a substrate 1 on which an active stack A has been provided. The active stack A is formed by an anode 2, which can comprise a transparent conductive oxide (TCO), such as for instance an ITO layer. Next, a PPV layer 3 has been applied and at least one electroluminescent layer 4. Onto that, a cathode 5 has been provided, for instance of a Barium-Aluminum combination. On top of the active stack A a thin-film encapsulation layer assembly E has been provided. The thin-film encapsulation layer assembly E comprises an inorganic layer 6, which is for instance an SiNₓ or SiOₓ layer. This layer has preferably been applied with a plasma deposition technique, which brings about a relatively high deposition rate. The inorganic layer 6 is preferably a ceramic or a dielectric layer such as the above-mentioned SiNₓ layer or an SiOₓ layer and the like.

The inorganic layer 6 forms a first sealing layer for the active stack A, which prevents moisture and/or oxygen from reaching and adversely affecting the functional layers of the active stack A. Provided on the inorganic layer 6 is an organic (polymer) layer 7, which can have a thickness of, for instance, 4-7 microns. Next, a metal layer 8 has been provided on the organic layer 7, before a further inorganic layer 9 has been applied. The metal layer 8 has been applied using a deposition technique which causes relatively little radiation, such as for instance CVD not being PECVD, evaporation, sputtering or other similar deposition techniques. As a result, the organic layer 7 is not affected by radiation during application of the metal layer 8. The metal layer 8 is further arranged so as to protect the organic layer 7 from radiation released during application of the next inorganic layer 9 through PECVD. In this way, the organic layer 7 is prevented from degrading and secreting materials that have an adverse influence on the functional layers of the active stack A. The metal layer 8 can have a same composition as the cathode 5. In this way, the metals that are used for the metal layer 8 are already present in the manufacturing process, which is advantageous from the viewpoint of cost. The metal layer 8 further provides an extra barrier, so that any moisture and/or oxygen needs to traverse a longer path to reach the active stack A, so that the active stack A is better protected from moisture and/or oxygen, which is favorable to the quality of the organic device.

The metal layer 8 is preferably a combination of a barium layer and an aluminum layer, the barium layer having for instance a thickness of between 2 and 10 nm and the aluminum layer having for instance a thickness of between 10 and 800 nm. The barium layer is then applied first, to obtain proper adhesion, and then the aluminum layer. The metal layer 8 further fulfills a getter function. The barium from the metal layer is capable of binding any unwanted gas molecules that may be detrimental to the active stack. It is also possible, however, that the metal layer 8 comprises chromium or a combination of lithium and aluminum or possibly other metals, such as copper, nickel, zinc, or tantalum. Also, the use of alloys is one of the possibilities. On the inorganic layer 9, if desired, an organic layer may be deposited, such as the organic layer 10 as represented in the exemplary embodiment of the invention in FIG. 1.

In another exemplary embodiment of the organic device O manufactured by means of the method according to the invention, it is possible that the thin-film encapsulation layer assembly E comprises a number of organic and inorganic layers applied to the active stack A in alternation. In such a design of the organic device O, on a number of organic layers or on all organic layers a metal layer may be deposited before an inorganic layer is applied onto them.

In yet another exemplary embodiment of the invention, the organic device O may be a top emitting device, such as for instance an active matrix display. In such a device, the cathode is provided on the substrate and the light-transmitting conductive layer is provided near the thin-film encapsulation layer assembly. In this embodiment, the thin-film encapsulation layer assembly is light-transmitting. This can for instance be realized by opting for a very thin metal layer.

It will be clear that the invention is not limited to the exemplary embodiment described but that various modifications are possible within the framework of the invention, as defined by the claims. Thus, in another embodiment of the invention, on the cathode 5, first an organic (polymer) layer may be applied, to which the metal layer is applied. Only then is the first inorganic layer applied. Further, it is also possible that a metal layer is provided on top of several organic layers from the thin-film encapsulation layer assembly. Further, it is clear that such a method for applying a thin-film encapsulation layer assembly can also be used in applying an encapsulation layer to other devices, for instance chips, LCDs and like devices where degradation of the organic layer upon application of an inorganic layer onto this organic layer is undesired.

1. A method for applying a thin-film encapsulation layer assembly to an organic device, wherein the organic device comprises a substrate which is provided with an active stack and is then provided with the thin-film encapsulation layer assembly for screening the active stack substantially from oxygen and moisture, wherein the thin-film encapsulation layer assembly is formed by applying at least one organic layer and at least one inorganic layer on the active stack, wherein the at least one inorganic layer is applied with plasma enhanced chemical vapor deposition (PECVD) or reactive sputtering, the method comprising:
applying a metal layer, after application of a first organic layer of the thin-film encapsulation layer assembly, to the first organic layer; and
applying an inorganic layer to the metal layer using PECVD or reactive sputtering, wherein the metal layer is applied to the first organic layer using a relatively low level radiation deposition technique in comparison to the technique for applying the inorganic layer, and wherein the metal layer is arranged to protect the organic layer from radiation during the subsequent PECVD or reactive sputtering process during the applying an inorganic layer step.

2. The method according to claim 1, wherein the PECVD procedure is a technique taken from the set of techniques consisting of: electron cyclotron resonance (ECR), inductively coupled plasma (ICP), or expanding thermal plasma (ETP).

3. The method according to claim 1, wherein the metal layer is of the same composition as a cathode present in the active stack.

4. The method according to claim 1, wherein the metal layer comprises barium and aluminum.

5. The method according to claim 1, wherein the metal layer is built up from a layer of barium having a layer thickness of between 2 and 10 nm, and thereon a layer of aluminum having a layer thickness of between 10 and 800 nm.

6. The method according to claim 1, wherein the metal layer comprises a simple metal or comprises a combination of an alkali metal and a metal.

7. The method according to claim 1, wherein the at least one inorganic layer is a ceramic or a dielectric layer.

8. The method according to claim 1, wherein the relatively low level radiation deposition technique used for depositing the metal layer comprises a chemical vapor deposition (CVD) that is not one of the set of techniques consisting, of: PECVD, evaporation, or sputtering.

9. The method according to claim 1, wherein when a thin-film encapsulation layer assembly, comprising a number of alternately applied organic and inorganic layers, is applied on the organic device, a metal layer is deposited on a number of organic layers of the thin-film encapsulation layer assembly applied on the organic device.

10. The method according to claim 1, wherein the organic device is a top emitting device wherein a cathode is provided on the substrate and wherein a light-transmitting conductive layer is provided near the thin-film encapsulation layer assembly, wherein the thin-film encapsulation layer assembly is light-transmitting.

11. The method according to claim 1, wherein a first applied inorganic layer of the thin-film encapsulation layer assembly is applied before the first organic layer of the thin-film encapsulation layer is applied.

12. The method according to claim 1, wherein a first applied inorganic layer of the thin-film encapsulation layer assembly is applied after the metal layer has been applied to the first organic layer of the thin-film encapsulation layer assembly.

13. An organic device manufactured according to the method of claim 1, wherein the organic device comprises:
an active stack; and
a thin-film encapsulation layer assembly, which covers the active stack, the thin-film encapsulation layer assembly comprising:
an inorganic layer applied with plasma enhanced chemical vapor deposition (PECVD) or reactive sputtering, and
a first applied organic layer, wherein at least one metal layer has been applied to the first applied organic layer before the inorganic layer has been applied to the thin-film encapsulation layer assembly using PECVD or reactive sputtering, wherein the metal layer has been applied to the organic layer using a relatively low level radiation deposition technique in comparison to the technique for applying the inorganic layer, wherein the metal layer protected the first applied organic layer from radiation during the subsequent application of the inorganic layer using PECVD or reactive sputtering.

14. The organic device according to claim 13, wherein the inorganic layers have been applied using the PECVD technique taken from the set of techniques consisting of: electron cyclotron resonance (ECR), inductively coupled plasma (ICP) or expanding thermal plasma (ETP).

15. The organic device according to claim 13, wherein the metal layer has the same composition as a cathode present in the active stack.

16. The organic device according to claim 13, wherein the metal layer comprises a combination of barium and aluminum.

17. The organic device according to claim 13, wherein the metal layer comprises a layer of barium having a layer thickness of between 2 and 10 nm and thereon a layer of aluminum having a layer thickness of between 10 and 800 nm.

18. The organic device according to claim 13, wherein the metal layer comprises a simple metal, or comprises a combination of an alkali metal and a metal.

19. The organic device according to claim 13, wherein the metal layer has been provided on the first organic layer utilizing a deposition technique that is not from the set of techniques consisting of: PECVD, evaporation or sputtering.

20. The organic device according to claim 13 wherein the organic device is an organic light emitting diode (OLED).
